(19) United States
(12) Patent Application Publication
(10) Pub. No.: US 2021/0336417 A1
(43) Pub. Date: Oct. 28, 2021

(54) OPTICAL APPARATUS

(71) Applicant: SUMITOMO ELECTRIC INDUSTRIES, LTD., Osaka (JP)

(72) Inventors: Jun-ichi HASHIMOTO, Osaka-shi (JP); Tsukuru KATSUYAMA, Osaka-shi (JP)

(73) Assignee: SUMITOMO ELECTRIC INDUSTRIES, LTD., Osaka (JP)

(21) Appl. No.: 17/224,766

(22) Filed: Apr. 7, 2021

(30) Foreign Application Priority Data
Apr. 28, 2020 (JP) 2020-079357

(51) Int. Cl. H01S 5/12; H01S 5/34; H01S 5/02212; H01S 5/22; H01S 5/227

(52) U.S. Cl. CPC H01S 5/12; H01S 5/3402; H01S 5/227; H01S 5/2206; H01S 5/02212

(57) ABSTRACT

An optical apparatus includes a light emitting module having a light emitting device, the light emitting device having a first semiconductor layer, a core layer, and a second semiconductor layer laminated in order, and an optical element on which a light emitted from the light emitting module is incident. The first semiconductor layer, the core layer, and the second semiconductor layer are arranged along a lamination direction. The lamination direction is inclined with respect to a direction perpendicular to an optical axis of the optical element.

### CROSS-REFERENCE TO RELATED APPLICATION

This application claims priority based on Japanese Patent Application No. 2020-079357 filed on Apr. 28, 2020, and the entire contents of the Japanese patent application are incorporated herein by reference.

### FIELD OF THE INVENTION

The present disclosure relates to an optical apparatus.

### BACKGROUND ART

A quantum cascade laser (QCL) is known as a small and low-cost light source. The QCL oscillating in a mid-infrared region is used for gas sensing or the like. Thierry Aellen, Stephane Blaser, Mattias Beck, Daniel Hofstetter, and Jerome Faist, “Continuous-wave distributed-feedback quantum-cascade lasers on a Peltier cooler,” Applied Physics Letters 83(10), pp 1929-1931 October 2003, referred to as Non-Patent Document 1, discloses a distributed-feedback (DFB)-type QCL that oscillates at a wavelength band of 9 μm.

### SUMMARY OF THE INVENTION

An optical apparatus according to one aspect of the present disclosure includes a light emitting module having a light emitting device, the light emitting device having a first semiconductor layer, a core layer, and a second semiconductor layer laminated in order, and an optical element on which a light emitted from the light emitting module is incident. The first semiconductor layer, the core layer, and the second semiconductor layer are arranged along a lamination direction. The lamination direction is inclined with respect to a direction perpendicular to an optical axis of the optical element.

### BRIEF DESCRIPTION OF THE DRAWINGS

FIG. 1 is a cross-sectional view illustrating a light emitting module according to one or more embodiments.

FIG. 2A is a perspective view illustrating a laser device according to one or more embodiments.

FIG. 2B is a cross-sectional view taken along line A-A in FIG. 2A.

FIG. 3A is a cross-sectional view taken along line B-B in FIG. 2A.

FIG. 3B is a cross-sectional view taken along line C-C in FIG. 2A.

FIG. 4 is a cross-sectional view illustrating an optical apparatus according to one or more embodiments.

FIG. 5 is a cross-sectional view illustrating a light emitting module according to a comparative example.

FIG. 6A is a perspective view illustrating a laser device according to one or more embodiments.

FIG. 6B is a cross-sectional view taken along line A-A in FIG. 6A.

FIG. 7 is a cross-sectional view illustrating an optical apparatus according to one or more embodiments.

FIG. 8 is a graph illustrating a measurement result of a far field pattern (FFP) in the Z-axis direction.

FIG. 9 is a cross-sectional view illustrating a light emitting module according to one or more embodiments.

FIG. 10 is a cross-sectional view illustrating a light emitting module according to one or more embodiments.

FIG. 11 is a cross-sectional view illustrating a light emitting module according to one or more embodiments.

FIG. 12 is a cross-sectional view illustrating a light emitting module according to one or more embodiments.

### DESCRIPTION OF THE PREFERRED EMBODIMENTS

In a light emitting module, a light emitting device such as a QCL is accommodated in a package. Output light from the light emitting module enters an optical element such as lenses and optical fibers. A portion of the incident light is reflected by the optical element, and the reflected light returns to a direction of the light emitting device. The reflected light is reflected by an output facet of the light emitting device and returns again to a direction of the optical element, thereby forming a Fabry-Perot (FP) resonator between the light emitting device and the optical element. Multiple reflections of light in the FP resonator cause components of interference mode included in output light to increase. Owing to the interference mode, noise components in output light of the light emitting device are increased. In response to the above issue, one or more aspects of the present disclosure are directed to provide an optical apparatus which can suppress noise components.

First, the contents of embodiments of the present disclosure will be listed and des cribed.

(1) An optical apparatus according to one embodiment of the present disclosure includes a light emitting module having a light emitting device, the light emitting device having a first semiconductor layer, a core layer, and a second semiconductor layer laminated in order, and an optical element on which a light emitted from the light emitting module is incident. The first semiconductor layer, the core layer, and the second semiconductor layer are arranged along a lamination direction. The lamination direction is inclined with respect to a direction perpendicular to an optical axis of the optical element. By inclining the lamination direction, an output facet of the light emitting device which is perpendicular to the lamination direction is inclined with respect to the optical axis of the optical element. By inclining the output facet of the light emitting device from the optical axis of the optical element, a light which is incident on the output facet after being reflected by the optical element is reflected by the output facet in a direction different from an incident direction along which the light is incident on the output facet from the optical element. Thus, an interference mode is less likely to occur between the output facet and the optical element. Consequently, the noise caused by the interference mode can be suppressed.

(2) The light emitting device may have a first region and a second region arranged along a propagation direction of the light. The first semiconductor layer may have a thickness greater than a thickness of the second semiconductor layer. The first semiconductor layer, the core layer, and the second semiconductor layer may form a mesa extending along the propagation direction of the light in the first region and the second region. The mesa in the second region may have a width in a direction intersecting with the propagation direction of the light smaller than a width of the mesa in the first region. A light distribution in the second region is wider than that in the first region. The first semiconductor layer is thick so that light is more widely distributed on a first semiconductor layer side than on a second semiconductor layer side. Thus, an optical axis at the second region is inclined from an optical axis at the first region. From the inclined output facet, light can be emitted in appropriate direction.

(3) The first semiconductor layer may have a semiconductor substrate and a first cladding layer. The second semiconductor layer may have a grating layer, a second cladding layer, and a contact layer. The grating layer may have a diffraction grating in the first region. The first semiconductor layer is thick so that light is more widely distributed on the first semiconductor layer side than on the second semiconductor layer side. Thus, the optical axis at the second region is inclined from the optical axis at the first region. The light emitting device has the diffraction grating so that it can oscillate at a single wavelength.

(4) The lamination direction along which the first semiconductor layer, the core layer, and the second semiconductor layer are laminated may be inclined with respect to the direction perpendicular to the optical axis of the optical element by a predetermined angle. The predetermined angle may be larger than 0 degrees and smaller than 90 degrees. A light incident on the output facet is reflected by the output facet in a direction different from the incident direction so that the noise can be suppressed.

(5) The lamination direction along which the first semiconductor layer, the core layer, and the second semiconductor layer are laminated may be inclined with respect to the direction perpendicular to the optical axis of the optical element by a predetermined angle. The predetermined angle may be greater than or equal to 1 degree and less than or equal to 15 degrees. Since the directions of the optical axis of the light emitting device and the optical axis of the optical element become closer, light coupling efficiencies of the optical element and the light emitting device can be enhanced. The light incident on the output facet is reflected by the output facet in a direction different from the incident direction so that the noise can be suppressed.

(6) The light emitting module may have an emitting window. The light emitting device and the optical element may face each other across the emitting window. The light may be incident on the emitting window perpendicularly. The light can be emitted from the light emitting module through the emitting window.

(7) The optical apparatus may further include a base and a cap provided on the base. The cap may have an emitting window and hermetically seal the light emitting device. The light emitting device and the optical element may face each other across the emitting window. The light emitting device is provided on the base so that the lamination direction is inclined with respect to an extending direction of the emitting window by a predetermined angle. The light emitting device can be protected from moisture, foreign matter, and the like by sealing it hermetically, and also the noise can be suppressed.

(8) The optical apparatus may further include a base, a first mount provided on the base, and a cap provided on the base. The cap may have an emitting window and hermetically seal the light emitting device and the first mount. The light emitting device and the optical element may face each other across the emitting window. The light emitting device may be mounted on a mounting surface of the first mount. The mounting surface of the first mount is inclined from a direction normal to the emitting window by a predetermined angle. The lamination direction may coincide with a direction normal to the mounting surface of the first mount. The mounting surface of the first mount is inclined so that the output facet of the light emitting device is inclined with respect to the direction normal to the emitting window, and thus the noise can be suppressed.

(9) The optical apparatus may further include a base, a first mount and a second mount provided on a first mounting surface of the base, and a cap provided on the first mounting surface of the base. The cap may have an emitting window and hermetically seal the light emitting device, the first mount, and the second mount. The light emitting device and the optical element may face each other across the emitting window. The first mount may be provided on a third mounting surface of the second mount. The light emitting device may be mounted on a second mounting surface of the first mount. The third mounting surface of the second mount may be inclined by a predetermined angle from a direction perpendicular to the emitting window so that the second mounting surface of the first mount is inclined from the direction perpendicular to the emitting window by the predetermined angle. The lamination direction may coincide with a direction normal to the second mounting surface of the first mount. The output facet of the light emitting device is inclined so that the noise can be suppressed.

(10) The optical apparatus may further include a base, a first mount and a second mount provided on a first mounting surface of the base, and a cap provided on the first mounting surface of the base. The cap may have an emitting window and hermetically seal the light emitting device, the first mount, and the second mount. The light emitting device and the optical element may face each other across the emitting window. The first mount may be provided on a third mounting surface of the second mount. The light emitting device may be mounted on a second mounting surface of the first mount. The first mounting surface of the base may be inclined by a predetermined angle from an extending direction of the emitting window so that the second mounting surface of the first mount is inclined from the direction perpendicular to the emitting window by the predetermined angle. The lamination direction may coincide with a direction normal to the second mounting surface of the first mount. The output facet of the light emitting device is inclined so that the noise can be suppressed.

### DESCRIPTION OF THE EMBODIMENTS

Hereinafter, embodiments of an optical apparatus according to the present disclosure will be described in detail with reference to the accompanying drawings. It should be noted that the present disclosure is not limited to these embodiments, but is indicated by the claims, and all changes that come within the meaning and range of equivalency of the claims are intended to be embraced therein.

### First Embodiment

### (Light Emitting Module)

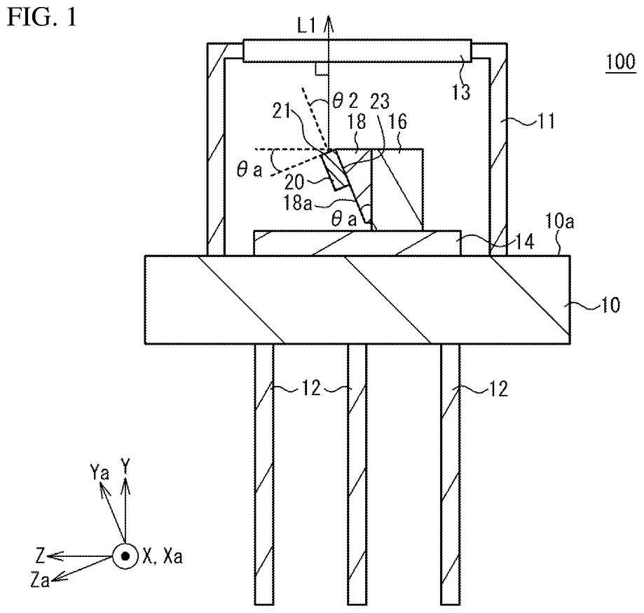

FIG. 1 is a cross-sectional view illustrating a light emitting module 100, in which a cross section taken along a light emission direction (Y-Z plane) is illustrated. As illustrated in FIG. 1, light emitting module 100 is a CAN-type package and includes a base 10, a cap 11, a temperature adjusting device 14, a mount block 16 (second mount), a sub-mount 18 (first mount), and a laser device 20.

A Y-axis direction is a thickness direction of base 10, and is an emission direction of light. One of the Y-axis direction may be described as an upward direction and the other as a downward direction. Mount block 16 and sub-mount 18 are aligned along a Z-axis direction. An X-axis direction, the Y-axis direction and the Z-axis direction are perpendicular to each other. An Xa-axis direction, a Ya-axis direction and a Za-axis direction are perpendicular to each other. The Xa-axis is parallel to the X-axis. The Ya-axis extends in a direction in which the Y-axis is rotated counterclockwise by an angle θa around X-axis serving as a rotary axis. The Za-axis extends in a direction in which Z-axis is rotated counterclockwise by angle θa around the X-axis serving as a rotary axis.

Base 10 has, for example, a disk shape with a diameter of 15 mm. A surface 10a (upper surface) of base 10 is a circular surface extending in an X-Z plane surface. Surface 10a has cap 11, mount block 16, and the like on its surface. A plurality of lead pins 12 protrudes in the Y-axis direction from a surface opposite to surface 10a of base 10. Lead pins 12 are electrically connected to temperature adjusting device 14 and laser device 20. Current for controlling temperature adjusting device 14 and laser device 20 is inputted through lead pins 12.

Cap 11 and temperature adjusting device 14 are provided on surface 10a of base 10. Mount block 16 is provided on an upper surface of temperature adjusting device 14. Sub-mount 18 is provided on a side surface of mount block 16. Laser device 20 is provided on a surface 18a (mounting surface) opposite to a side of sub-mount 18 facing mount block 16.

Cap 11 and temperature adjusting device 14 are fixed on surface 10a of base 10 by soldering or the like. Mount block 16 is fixed on temperature adjusting device 14 by soldering or the like. Sub-mount 18 is fixed on mount block 16 by soldering or the like. Laser device 20 is fixed on surface 18a of sub-mount 18 by soldering or the like. With base 10 and cap 11, temperature adjusting device 14, mount block 16, sub-mount 18 and laser device 20 are hermetically sealed within light emitting module 100.

Cap 11 is formed of a metal, such as an iron-nickel (Fe—Ni) alloy, an iron-nickel-cobalt (Fe—Ni—Co) alloy, stainless steel, or iron. Lead pins 12 are formed of metals. Base 10 and mount block 16 are formed of a metal such as gold-plated stainless steel, copper (Cu), copper tungsten alloy (CuW), and the like. Sub-mount 18 is formed of a material having a high thermal conductivity. The material includes a metal such as Cu and CuW alloys, and ceramics such as aluminum nitride (AlN) and diamond. Temperature adjusting device 14 is, for example, a Thermo Electric Cooler in which Peltier elements are used for controlling a temperature.

Cap 11 has an emitting window 13. Emitting window 13 is made of a material having low absorptivity with respect to output light from laser device 20, which is mid-infrared light. The materials of emitting window 13 are, for example, zinc selenide (ZnSe), zinc nitride (ZnS), and germanium (Ge). Emitting window 13 faces base 10 and laser device 20. A surface of emitting window 13 facing base 10 and another surface on the back of the surface are parallel to the X-axis direction and the Z-axis direction, and perpendicular to the Y-axis direction.

Mount block 16 is rectangular in shape. Sub-mount 18 is formed in a rectangular prism shape with a trapezoidal base surface. A surface of sub-mount 18, which faces emitting window 13, extends parallel to the X-Z plane surface, and a surface adjoining mount block 16 of sub-mount 18 extends parallel to an X-Y plane surface. Surface 18a of sub-mount 18 is inclined by angle θa (predetermined angle) with respect to the Y-axis direction, and extends parallel to the Ya-axis. The Za-axis is a normal of surface 18a.

Laser device 20 is rectangular in shape. Laser device 20 has a surface 21 (output facet) and a surface 23, which are perpendicular to each other. Surface 23 of laser device 20 contacts surface 18a (mounting surface) of sub-mount 18. Since surface 18a is inclined with respect to the Y-axis direction, laser device 20 is also inclined from the Y-axis direction. Surface 21 of laser device 20 is a surface for emitting output light, and is facing emitting window 13. Surface 21 is non-parallel to emitting window 13. Surface 21 extends in the Za-axis direction, and is inclined by angle θa from the Z-axis direction in which emitting window 13 extends. The Ya-axis is a normal of surface 21.

### (Laser Device)

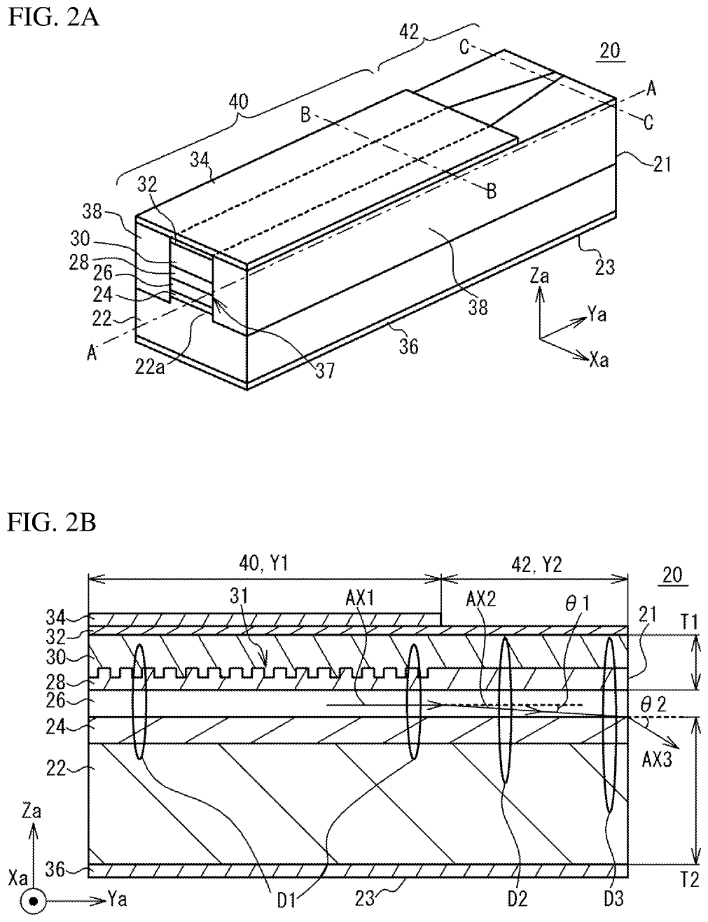

FIG. 2A is a perspective view in which laser device 20 is illustrated. FIG. 2B is a cross-sectional view taken along line A-A of FIG. 2A. As illustrated in FIGS. 2A and 2B, laser device 20 contains a first region 40 and a second region 42. First region 40 and second region 42 extend in the Ya-axis direction and second region 42 is connected to one end of first region 40. Surface 21 is located at a side of second region 42 where is opposite to first region 40. The sides of surface 21 extend in the Xa-axis direction and the Za-axis direction. A length Y1 of first region 40 is, for example, 1 mm, and a length Y2 of second region 42 is, for example, 200 μm.

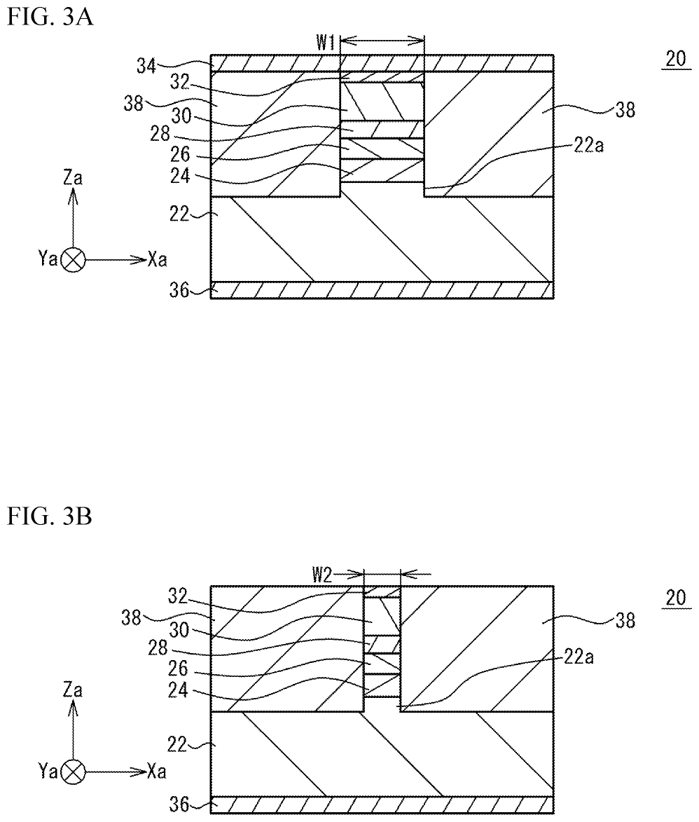

Laser device 20 is a quantum cascade laser (QCL) device having a substrate 22, a lower cladding layer 24, a core layer 26, a grating layer 28, an upper cladding layer 30, a contact layer 32, an embedding region 38, and electrodes 34 and 36. In FIGS. 2B to 3B, substrate 22 and lower cladding layer 24 are semiconductor layers positioned below core layer 26 (first semiconductor layer). Grating layer 28, upper cladding layer 30 and contact layer 32 are semiconductor layers (second semiconductor layer) positioned above core layer 26.

Substrate 22 is a semiconductor substrate formed of, for example, n-type indium phosphorus (n-InP) having a thickness of 100 μm. Lower cladding layer 24 and upper cladding layer 30 are formed of, for example, n-InP having a thickness of 2 μm. Core layer 26 has, for example, an active layer with an aluminum indium arsenide/gallium indium arsenide (AlInAs/GaInAs) superlattice and an injection layer with an AlInAs/GaInAs superlattice. Grating layer 28 is formed of n-type gallium indium arsenide (n-GaInAs) having a thickness of, for example, 0.5 μm. Contact layer 32 is formed of, for example, 0.1-μm-thick n-GaInAs. Embedding region 38 is formed of, for example, Fe-doped InP.

FIG. 3A is a cross-sectional view taken along line B-B in FIG. 2A. FIG. 3B is a cross-sectional view taken along line C-C in FIG. 2A. As illustrated in FIGS. 2A, 3A and 3B, a central portion in the Xa-axis direction of substrate 22 is a protruding portion 22a which protrudes further than the other portions in the Za-axis direction. On protruding portion 22a of substrate 22, lower cladding layer 24, core layer 26, grating layer 28, upper cladding layer 30 and contact layer 32 are laminated in this order. As illustrated in FIG. 2B, the Za-axis direction is a lamination direction, and surface 21 extends in the Za-axis direction and the Xa-axis direction.

Protruding portion 22a of substrate 22, lower cladding layer 24, core layer 26, grating layer 28, upper cladding layer 30 and contact layer 32 form a mesa 37. Embedding region 38 is provided on substrate 22 and on both sides of mesa 37. When laser device 20 is mounted on surface 18a of sub-mount 18 as illustrated in FIG. 1, substrate 22 is located on surface 18a side, and contact layer 32 is located on the other side of sub-mount 18 away from surface 18a.

As illustrated in FIG. 2A, mesa 37 and embedding region 38 extend from first region 40 through second region 42 to reach surface 21 along the Ya-axis direction. When viewed from Za-axis direction, Ya-axis direction is parallel to a propagation direction of a light along which the light generated in core layer 26 propagates. Width of mesa 37 in the Xa-axis direction is constant in first region 40 and gradually decreases in second region 42. As illustrated in FIG. 3A, a width W1 of mesa 37 in first region 40 is, for example, 5 μm. As illustrated in FIG. 3B, a width W2 of mesa 37 in second region 42 is less than width W1. Width W2 of surface 21 is, for example, 1 μm. Mesa 37 functions as an optical waveguide of the light.

As illustrated in FIG. 2B, in first region 40, periodic concavities and convexities are provided on a surface of grating layer 28 in contact with upper cladding layer 30, and the concavities and convexities function as a diffraction grating 31. In second region 42, the surface of grating layer 28 in contact with upper cladding layer 30 is flat, and diffraction grating 31 is not provided.

As illustrated in FIGS. 2A and 2B, electrode 34 is provided on a principal surfaces of contact layer 32 and embedding region 38. Electrode 34 is provided in first region 40 and not in second region 42. Electrode 36 is provided on a surface of substrate 22, the surface being opposite to electrode 34. Electrode 36 is provided in first region 40 and second region 42.

By applying voltages to electrodes 34 and 36, carriers are injected into core layer 26. The carrier injections cause core layer 26 to generate light. The light propagates in mesa 37 in the Ya-axis direction in first region 40. The wavelength of the light is selected by diffraction grating 31. Laser device 20 is a distributed feedback (DFB)-type QCL device that oscillates with the selected wavelength. In first region 40, the light is generated and the wavelength of the light is selected. Laser device 20 oscillates in the mid-infrared region, for example, at the wavelength between 3 μm and 20 μm. Second region 42 functions as a spot size converter (SSC) that transforms the size of the light distribution.

Ellipses D1, D2 and D3 of FIG. 2B represent light distributions within laser device 20. An optical axis AX1 is an optical axis of light propagating through first region 40. An optical axis AX2 is an optical axis of light propagating through second region 42. An optical axis AX3 is an optical axis of light emitted from surface 21. The dotted line is an imaginary line along the Ya-axis direction. As illustrated in FIG. 2B, optical axis AX1 in first region 40 is directed along the Ya-axis direction and perpendicular to surface 21. Each of the optical axes is the line through which the centers of the light distributions are passing in each area of laser device 20.

As illustrated in FIG. 3B, width W2 of mesa 37 in second region 42 is less than width W1 in first region 40. As the width of mesa 37 decreases, the light confinement in core layer 26 decreases so that the light is more widely distributed out of core layer 26. As illustrated in FIG. 2B, as light propagates through second region 42, the light is distributed into a region indicated by ellipse D2 which is wider than that of D1, and then into a region indicated by ellipse D3 which is wider than that of D2. Since the light inside laser device 20 is distributed widely in the SSC, far field pattern (FFP) corresponding to a spreading of the light emitted from the output facet is reduced.

A thickness T1 of layers positioned above core layer 26 (the total thickness of grating layer 28, upper cladding layer 30 and contact layer 32) is, for example, 2 μm to 3 μm. The thickness T2 of layers positioned below core layer 26 (the total thickness of lower cladding layer 24 and substrate 22) is greater than the thickness T1, and for example, 100 μm. In a region positioned above core layer 26, light distributes until it reaches contact layer 32 but not beyond contact layer 32. This is due to the fact that the upper side of contact layer 32 in second region 42 is an air or an insulating film (not illustrated), which has a lower refractive index than semiconductor. Because the total thickness of layers positioned below core layer 26 is greater than that of layers positioned above core layer 26, light is more widely distributed into a lower side of core layer 26 than an upper side of core layer 26.

As light propagates through second region 42 toward surface 21, the light spreads toward substrate 22 and is distributed more widely, as shown by ellipses D2 and D3 in FIG. 2B. Optical axis AX2 in second region 42 is thus inclined from optical axis AX1 toward substrate 22. Light is emitted from surface 21 to outside of laser device 20. The refractions in surface 21 cause optical axis AX3 outside surface 21 to further incline from the Ya-axis direction, which means that optical axis AX3 of output light is not perpendicular to surface 21. An inclination angle θ2 of optical axis AX3 with respect to the Ya-axis direction is, for example, 10 degrees, which is greater than an inclination angle θ1 of optical axis AX2 with respect to the Ya-axis direction and equal to angle θa shown in FIG. 1.

As illustrated in FIG. 1, surface 18a of sub-mount 18 is inclined from Y-axis direction perpendicular to emitting window 13 and extends along the Ya-axis direction. Laser device 20, disposed on surface 18a, is inclined from a direction perpendicular to emitting window 13, and extends along the Ya-axis direction. Surface 21 of laser device 20 is inclined by angle θa from an extending direction (Z-axis direction) of emitting window 13, and extends along the Za-axis direction. An inclination angle θa of surface 21 from the Z-axis direction is equal to inclination angle θ2 of optical axis AX3 from the Ya-axis direction illustrated in FIG. 2B. Therefore, as illustrated in FIG. 1, light L1 emitted from surface 21 propagates in the Y-axis direction and is incident on emitting window 13 perpendicularly.

### (Optical Apparatus)

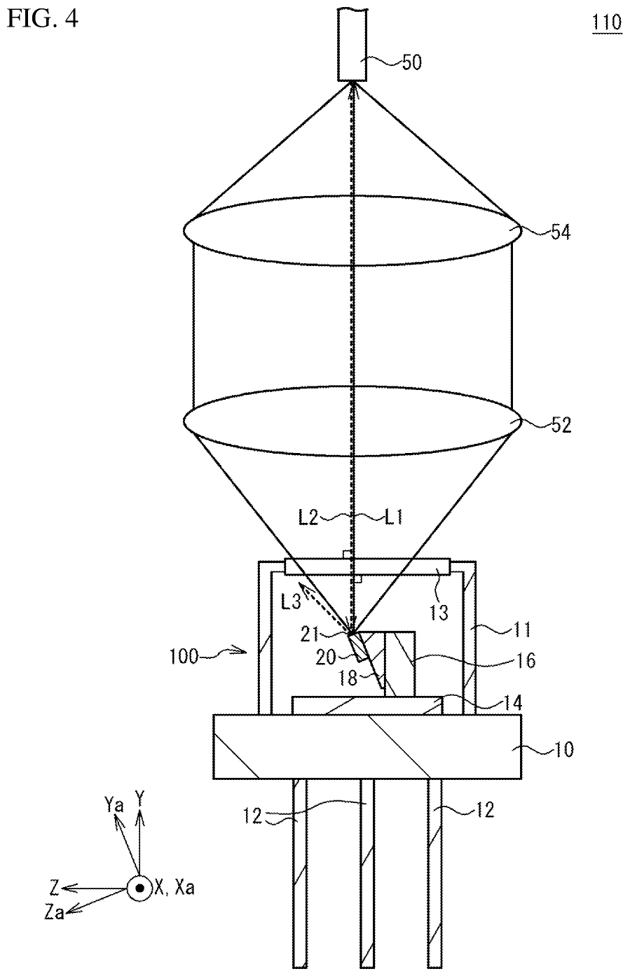

FIG. 4 is a cross-sectional view illustrating an optical apparatus 110. Optical apparatus 110 includes light emitting module 100 and optical elements including an optical fiber 50, and lenses 52 and 54. Lens 52, lens 54 and optical fiber 50 are arranged in this order from a side closer to light emitting module 100 in the Y-axis direction. Each optical axis of lens 52, lens 54, and optical fiber 50 extends in the Y-axis direction. Emitting window 13 is perpendicular to optical axis of each optical element such as optical fiber 50. Surface 21 of laser device 20 is inclined by angle θa with respect to Z-axis direction which is perpendicular to optical axis of optical fiber 50 and the like. Optical apparatus 110 may include optical elements other than lenses and optical fibers.

Lenses 52 and 54 face surface 21 of laser device 20 across emitting window 13. Lenses 52 and 54 are formed of, for example, ZnSe as with emitting window 13 so that output light L1 from laser device 20, which is mid-infrared light, is less likely to be absorbed. Lens 52 is a collimating lens. Lens 54 is a condenser lens. One end (end surface) of the optical fiber 50 faces surface 21 of laser device 20 across emitting window 13. The other end of the optical fiber 50 is coupled to an analyte such as a gas cell (not illustrated).

Light L1 emitted from surface 21 of light emitting module 100 is incident on emitting window 13 of cap 11 perpendicularly and passes perpendicularly through emitting window 13. Light L1 is collimated by lens 52, condensed by lens 54, and incident on one end of the optical fiber 50. Light L1 is incident on a gas cell (not illustrated) through the optical fiber 50, so that gas sensing is performed.

A portion of output light L1 from light emitting module 100 is reflected by an incident surface and an emitting surface of lens 52, an incident surface and an emitting surface of lens 54, and the end surface of the optical fiber 50. In FIG. 4, among the reflected lights, reflected light L2 from the end surface of the optical fiber 50 is indicated by a dotted line. Reflected light L2 propagates in the Y-axis direction, is incident on emitting window 13 perpendicularly, passes through emitting window 13, and is reflected again by surface 21 of laser device 20.

Surface 21 is inclined from the Z-axis direction which is the extending direction of emitting window 13, and is not perpendicular to the Y-axis. Light L2 is thus incident on surface 21 from a direction that is not perpendicular to surface 21. Most of light L2 is reflected in a direction different from the incident direction (Y-axis direction) by surface 21. Light L3 reflected by surface 21 propagates in a direction different from the incident direction of light L2, and thus less likely to return to the one end of the optical fiber 50. Reflected light from lens 52 and the reflected light from lens 54 are incident on surface 21 of laser device 20 as with reflected light L2, and is reflected in a direction different from the incident direction (Y-axis direction) by surface 21.

### COMPARATIVE EXAMPLE

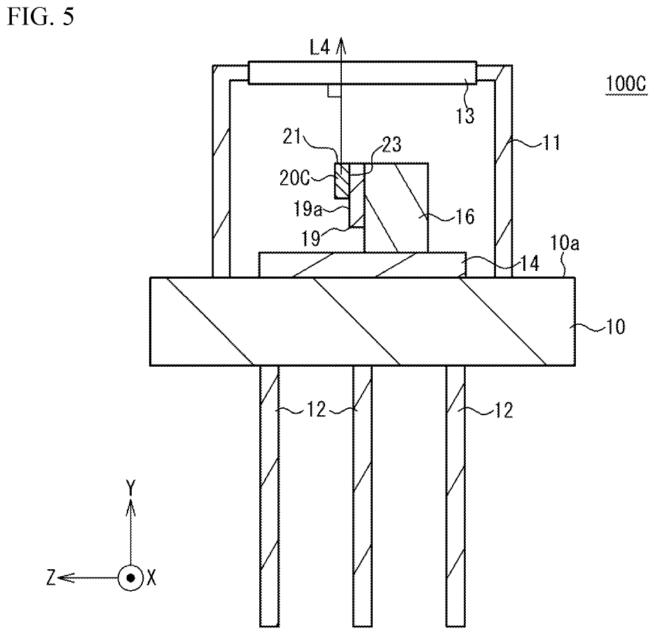

FIG. 5 is a cross-sectional view illustrating a light emitting module 100C according to a comparative example. Descriptions of the same configuration as those of the first embodiment are omitted. A sub-mount 19 is rectangular. A surface 19a of sub-mount 19 extends in the Y-axis direction and is perpendicular to emitting window 13. A laser device 20C is mounted on surface 19a. Surface 21 of laser device 20C extends in the Z-axis direction and is parallel to emitting window 13. Light L4 emitted from surface 21 propagates in the Y-axis direction and is incident on emitting window 13 perpendicularly.

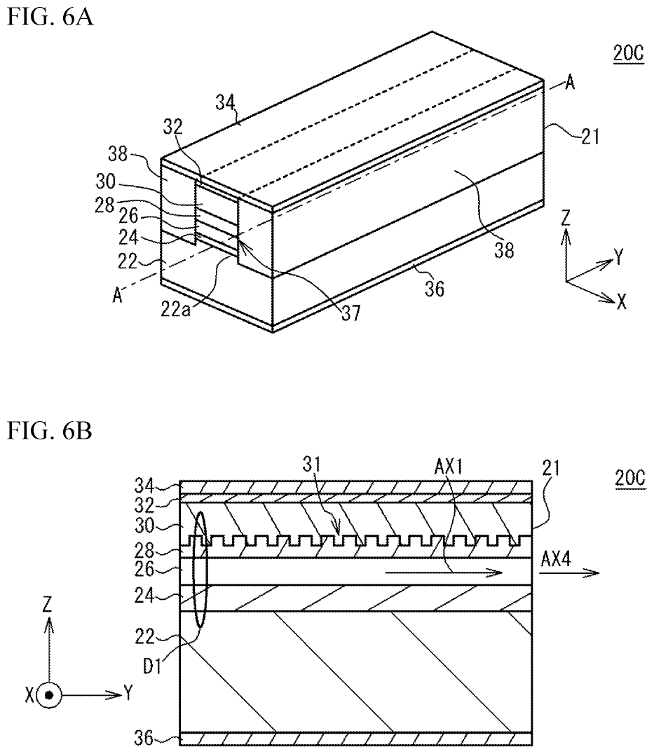

FIG. 6A is a perspective view illustrating a laser device 20C according to a comparative example. FIG. 6B is a cross-sectional view taken along line A-A in FIG. 6A. Laser device 20C does not include second region 42. Width W1 of mesa 37 is constant, and for example, 5 μm. Light thus reaches surface 21 while maintaining a light distribution as indicated by ellipse D1. Optical axis AX1 of laser device 20C and an optical axis AX4 of output light are directed along the Y-axis direction and are perpendicular to surface 21.

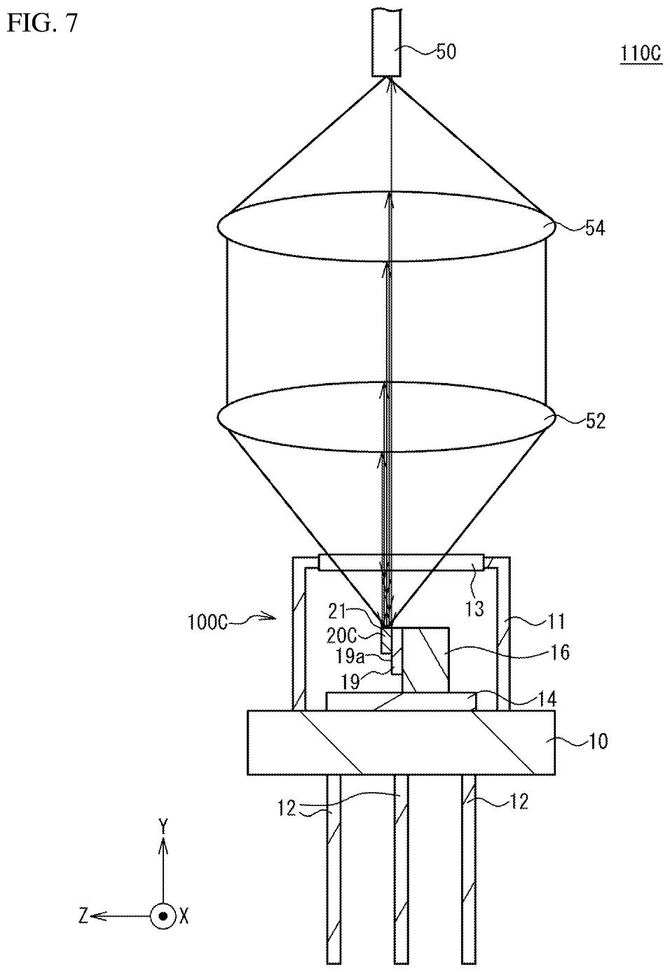

FIG. 7 is a cross-sectional view illustrating an optical apparatus 110C. Optical apparatus 110C includes light emitting module 100C, optical fiber 50, and lenses 52 and 54.

A portion of output light of light emitting module 100C is reflected by the incident surface and the emitting surface of lens 52, the incident surface and the emitting surface of lens 54, and the end surface of optical fiber 50. The reflected light incident on emitting window 13 perpendicularly enters surface 21 of laser device 20 perpendicularly after passing through emitting window 13, and is reflected again by surface 21. Since surface 21 is parallel to emitting window 13, the reflected light is incident on surface 21 perpendicularly, and is reflected by surface 21 in the Y-axis direction which is the incident direction. Light reflected by surface 21 is further reflected at the incident surface and the emitting surface of lens 52, the incident surface and the emitting surface of lens 54, and the end surface of optical fiber 50.

As illustrated by arrows in FIG. 7, a Fabry-Perot (FP) resonator is formed between surface 21 of laser device 20 and each of the incident surface and the emitting surface of lens 52, the incident surface and the emitting surface of lens 54, and the end surface of the optical fiber 50. Multiple reflections of light are generated in the resonator, and the interference mode is generated. Laser device 20 is a QCL which emits coherent light, in which the interference mode is likely to occur. The interference mode generates the noise, and causes deterioration of an accuracy of sensing such as gas sensing.

On the other hand, according to the first embodiment, as illustrated in FIG. 1 and FIG. 4, surface 21 of laser device 20 extends in the Za-axis direction which is a lamination direction of the semiconductor layer, and is inclined by angle θa from the Z-axis direction which is a direction perpendicular to the optical axis of an optical element such as optical fiber 50. Output light L1 of light emitting module 100 is reflected by optical fiber 50, lens 52, and lens 54. The reflected light is reflected by surface 21 of laser device 20 in a direction different from the incident direction. The FP resonator is less likely to be formed between surface 21 and each of the incident surface and the emitting surface of lens 52, the incident surface and the emitting surface of lens 54, and the end surface of optical fiber 50, thereby reducing an occurrence of multiple reflections of light. As a result, the interference mode due to the FP resonator hardly occurs and the noise caused by the interference mode can be suppressed.

Inclination angle θa of surface 21 of laser device 20 is, for example, greater than 0 degrees and less than 90 degrees, and for example, greater than or equal to 1 degree and less than or equal to 10 degrees. Angle θa may be, for example, 2 degrees or more, 5 degrees or more, or 6 degrees or less, 8 degrees or less, 12 degrees or less, or 15 degrees or less. Light reflected by surface 21 can be diverted from the Y-axis direction, and the noise can be suppressed.

As illustrated in FIG. 1, light emitting module 100 containing laser device 20 can be hermetically sealed by cap 11 having emitting window 13 so as to protect laser device 20 from water, foreign matter, and the like. Surface 21 is inclined by angle θa with respect to the extending direction of emitting window 13. Light incident on surface 21 is reflected in a direction different from the incident direction so that the noise caused by the interference mode can be suppressed. Light emitting module 100 may have a configuration other than a CAN-type package.

Output light L1 from surface 21 is incident on emitting window 13 perpendicularly and then emitted outward from emitting window 13. Output light L1 propagates along an optical axis of optical elements which include optical fiber 50, enters optical fiber 50 or the like and then is utilized for the gas sensing. An angle between output light L1 and emitting window 13 may be exactly 90°, or it may be within a range of, for example, 90 degrees±1 degree, or 90 degrees±5 degrees. Light emitting module 100 may be used for purposes other than the gas sensing.

As illustrated in FIG. 1, the Y-axis direction is a direction perpendicular to emitting window 13. Surface 18a of sub-mount 18 is inclined by angle θa from the Y-axis direction, and extends in the Ya-axis direction. Since laser device 20 is mounted on surface 18a, it is inclined by angle θa as with surface 18a. Surface 21 of laser device 20 is directed along the Za-axis direction which is the normal direction of surface 18a, and is inclined by angle θa from the Z-axis direction which is the extending direction of emitting window 13. The light incident on surface 21 is reflected in a direction different from the Y-axis direction so that the noise can be suppressed.

Sub-mount 18 is a rectangular prism with a trapezoidal base surface or a triangular prism which can be formed by, for example, inclining surface 18a through cutting rectangular sub-mount 18. Other conceivable methods for suppressing multiple reflections may include inclining emitting window 13 to make it a tilt window, or performing an antireflection coating or the like on lens 52 and lens 54. Compared to these methods, manufacturing of sub-mount 18 is simplified so that the manufacturing cost is reduced.

As illustrated in FIGS. 2A and 2B, laser device 20 has first region 40 and second region 42. As illustrated in FIGS. 2A to 3B, laser device 20 has substrate 22, lower cladding layer 24, core layer 26, grating layer 28, upper cladding layer 30 and contact layer 32 stacked in order. The layers from substrate 22 to contact layer 32 form mesa 37. Mesa 37 extends in first region 40 and second region 42 along the propagation direction of light propagating in laser device 20. Width W2 of mesa 37 in second region 42 illustrated in FIG. 3B is smaller than width W1 in first region 40 illustrated in FIG. 3A. This results in a weaker optical confinement in mesa 37 in second region 42. Light is more widely distributed into second region 42 than into first region 40, and diffuses from core layer 26.

As illustrated in FIG. 2B, the total thickness T2 of substrate 22 and lower cladding layer 24, is greater than the total thickness T1 of grating layer 28, upper cladding layer 30 and contact layer 32. Thus, light is more widely distributed in lower cladding layer 24 than in upper cladding layer 30. Optical axis AX2 in second region 42 is inclined with respect to optical axis AX1 in first region 40. Optical axis AX3 of light emitted from surface 21 is inclined from optical axes AX1 and AX2 and inclined by angle θ2 with respect to the Ya-axis direction. Inclination angle θ2 of optical axis AX3 is equal to inclination angle θa of surface 21 so that output light L1 is perpendicular to emitting window 13.

Laser device 20 is a DFB-type device having diffraction grating 31 provided on grating layer 28. Laser device 20 oscillates with, for example, a single wavelength in the mid-infrared range. Gas sensing and the like are possible by using mid-infrared light. In particular, laser device 20 is a DFB-type QCL in one or more embodiments. Laser device 20 emits light of single wavelength so that gas sensing and the like can be performed with high accuracy. Oscillating wavelength may be of a wavelength band other than the mid-infrared band. Laser device 20 may be the light emitting device other than a QCL.

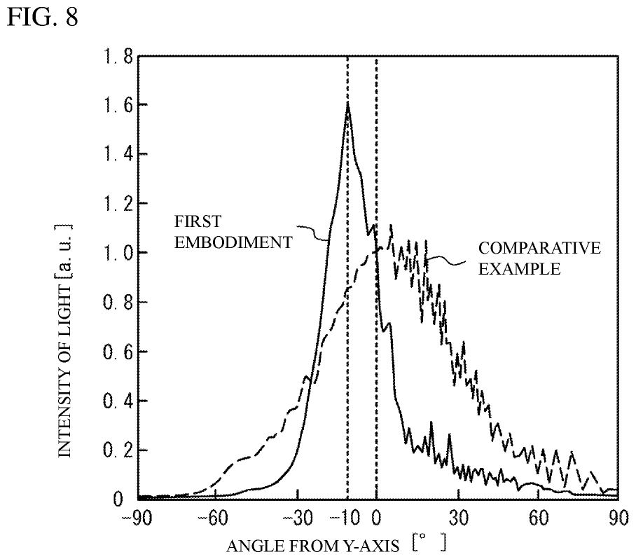

FIG. 8 is a graph illustrating measurement results of a far-field image (FFP) in the Z-axis direction. A horizontal axis represents an angle from a direction perpendicular to surface 21 (Y-axis direction). A vertical axis represents an intensity of light which is normalized by an intensity of the 0-degree angles. A solid line represents the first embodiment and a dashed line represent a comparative example. The materials and the dimensions of laser device 20 are as described above.

As illustrated in FIG. 8, in the first embodiments illustrated by the solid line, the FFP of output light is smaller than that of the comparative example illustrated by the dashed line. The FFP in the comparative example is, for example, 55 degrees. The FFP in the first embodiment is, for example, 26 degrees, which is a half of the FFP in the comparative example. This is because, second region 42 functioning as an SSC is integrated in laser device 20 as illustrated in FIGS. 2A and 2B.

A peak position of the FFP in the comparative example is about 0 degrees. This is because optical axis AX4 in the comparative example is perpendicular to surface 21 as illustrated in FIG. 5B. On the other hand, a peak position of the FFP in the first embodiment is approximately −10 degrees. This is because, optical axis AX3 is inclined by angle θ2 from the normal direction of surface 21 as illustrated in FIG. 2B.

By changing the thicknesses T1 and T2, inclination angle θ2 of optical axis AX3 can be adjusted. As thickness T1 becomes smaller and thickness T2 becomes larger, light is more widely distributed into substrate 22 side so that inclination angle θ2 becomes larger. Angle θ2 may be exactly equal to angle θa or different from angle θa within a range of, for example, ±0.1 degrees or ±0.5 degrees.

### Second Embodiment

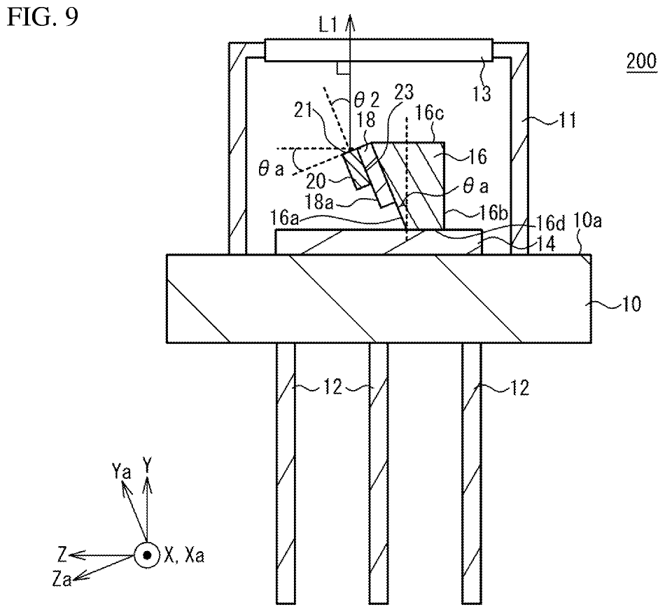

FIG. 9 is a cross-sectional view illustrating a light emitting module 200 according to a second embodiment. Descriptions of the same configuration as those of the first embodiment are omitted. As illustrated in FIG. 9, the shape of mount block 16 is a rectangular prism having a trapezoidal base surface. A surface 16c and a surface 16d of mount block 16 face each other, are parallel to each other, and extend in the Z-axis direction. Surface 16d contacts temperature adjusting device 14. Surface 16c faces emitting window 13. A surface 16a and a surface 16b are opposed to each other. Surface 16b is perpendicular to surfaces 16c and 16d and extends in the Y-axis direction. Surface 16a (mounting surface) is not perpendicular to surface 16c and surface 16d and is not parallel to surface 16b. Surface 16a is inclined by angle θa from the Y-axis direction, and extends in the Ya-axis direction.

Sub-mount 18 which is rectangular in shape is mounted on surface 16a of mount block 16. Surface 18a of sub-mount 18 is thus inclined in the Ya-axis direction as with surface 16a of mount block 16. Laser device 20 is mounted on surface 18a. Surface 21 of laser device 20 is inclined from the Z-axis direction by angle θa and extends in the Za-axis direction. In optical apparatus 110 of FIG. 4, light emitting module 200 can be used instead of light emitting module 100.

According to the second embodiment, as with the first embodiment, light incident on surface 21 is reflected in a direction different from the Y-axis direction which is the incident direction, so that the noise can be suppressed. Since sub-mount 18 is formed of ceramics such as AlN and diamond which are harder than metals, it is hard to cut sub-mount 18. Mount block 16 formed of a metal such as Cu and CuW can be easily cut as compared with sub-mount 18. The shape of mount block 16 may be the rectangular prism having the trapezoidal base surface, or may be the triangular prism, or the like.

### Third Embodiment

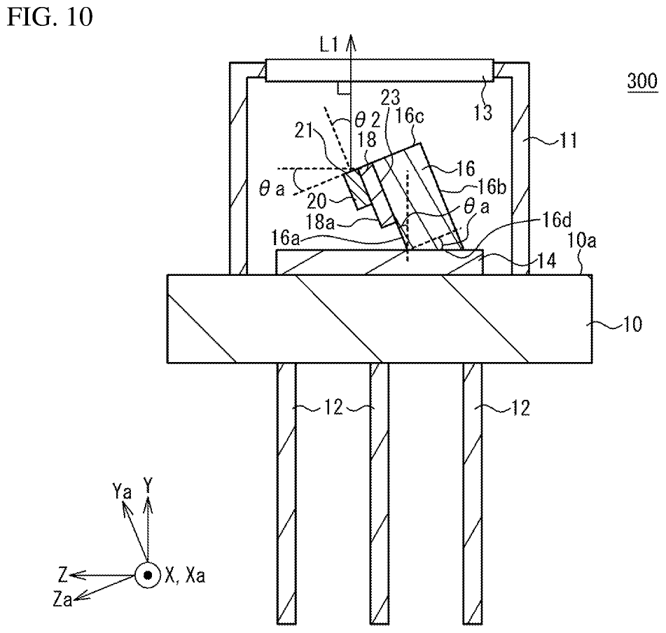

FIG. 10 is a cross-sectional view illustrating a light emitting module 300 according to a third embodiment. Descriptions of the same configuration as those of the first embodiment are omitted. As illustrated in FIG. 10, the shape of mount block 16 is the rectangular prism having the trapezoidal base surface. Surface 16c is perpendicular to surface 16a and 16b, is inclined from the Z-axis direction, and extends in the Za-axis direction. Surface 16d is not perpendicular to surface 16a and 16b, is inclined by angle θa from the direction parallel to surface 16c (Za-axis direction), and extends in the Z-axis direction. Surface 16d is placed on temperature adjusting device 14. Surface 16a and 16b are parallel to each other, are inclined by angle θa from the Y-axis direction, and extend in the Ya-axis direction.

Sub-mount 18 which is rectangular in shape is mounted on surface 16a of mount block 16. Surface 18a of sub-mount 18 is inclined in the Ya-axis direction as with surface 16a of mount block 16. Laser device 20 is mounted on surface 18a. Surface 21 of laser device 20 is inclined by angle θa from the Z-axis direction and extends in the Za-axis direction. In optical apparatus 110 in FIG. 4, light emitting module 300 can be used instead of light emitting module 100.

According to the third embodiment, as with the first embodiment, the light incident on surface 21 is reflected in a direction different from the Y-axis direction which is the incident direction, so that the noise can be suppressed. Mount block 16 formed of a metal such as Cu and CuW can be easily cut as compared with sub-mount 18. Surface 16a of mount block 16 is parallel to surface 16b, and hence die bonding of sub-mount 18 onto surface 16a and die bonding of laser device 20 onto sub-mount 18 are easy as compared with the case where surface 16a is inclined with respect to surface 16b. This simplifies a manufacturing step and improves manufacturing yield. The shape of mount block 16 may be the rectangular prism having the trapezoidal base surface, or may be the triangular prism or the like.

### Fourth Embodiment

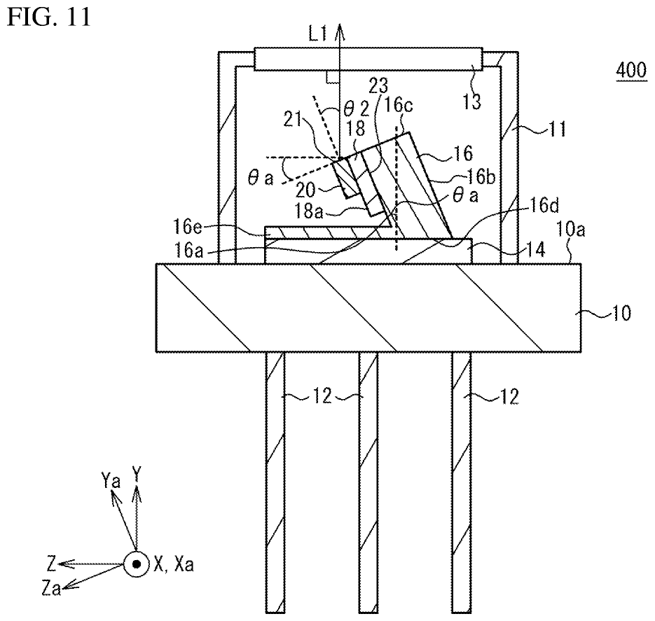

FIG. 11 is a cross-sectional view illustrating a light emitting module 400 according to a fourth embodiment. Descriptions of the same configurations as those of the third embodiment are omitted. As illustrated in FIG. 11, mount block 16 has an extension portion 16e. Extension portion 16e extends from surface 16a in the Z-axis direction and is located above temperature adjusting device 14. In optical apparatus 110 of FIG. 4, light emitting module 400 can be used instead of light emitting module 100.

According to the fourth embodiment, as with the first embodiment, the light incident on surface 21 is reflected in a direction different from the Y-axis direction which is the incident direction. Thus, the noise can be suppressed. Extension portion 16e of mount block 16 helps to stabilize the mount block 16 and prevents the mount block 16 from falling down. A contact surface between mount block 16 and temperature adjusting device 14 is increased. The heat of laser device 20 is easily transferred to temperature adjusting device 14 through sub-mount 18 and mount block 16. Therefore, the thermal control of laser device 20 is effectively performed.

### Fifth Embodiment

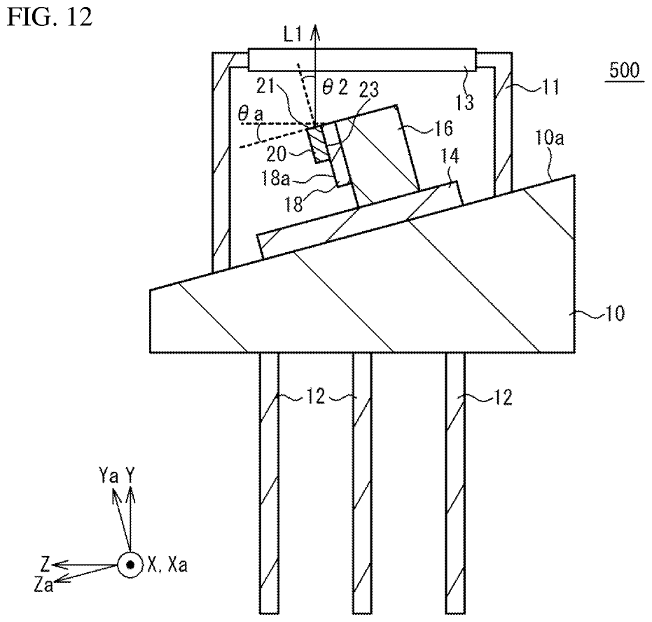

FIG. 12 is a cross-sectional view illustrating a light emitting module 500 according to the fifth embodiment. Descriptions of the same configuration as those of the first embodiment are omitted. As illustrated in FIG. 12, temperature adjusting device 14, mount block 16, sub-mount 18 and laser device 20 are, for example, rectangular in shape. Surface 10a of base 10 is inclined by angle θa from the Z-axis direction, and extends in the Za-axis direction. Because surface 10a is inclined, temperature adjusting device 14, mount block 16, sub-mount 18 and laser device 20 are also inclined. Surface 18a of sub-mount 18 is inclined by angle θa from the Y-axis direction, and extends in the Ya-axis direction. Surface 21 of laser device 20 is inclined by angle θa from the Z-axis direction and extends in the Za-axis direction. In optical apparatus 110 of FIG. 4, light emitting module 500 can be used instead of light emitting module 100.

According to the fifth embodiment, as with the first embodiment, light incident on surface 21 is reflected in a direction different from the Y-axis direction which is the incident direction. Thus, the noise can be suppressed. Since mount block 16 and sub-mount 18 may be rectangular, the mounting step is simplified and the manufacturing yield is improved. A manufacturing step of mount block 16 and sub-mount 18 is simplified since the process of making the inclined surface can be omitted.

Although the embodiments of the present disclosure have been described above in detail, the present disclosure is not limited to any particular embodiment, and various modifications and variations are possible within the scope of the gist of the present disclosure described in the claims.

What is claimed is:

1. An optical apparatus comprising:
a light emitting module having a light emitting device, the light emitting device having a first semiconductor layer, a core layer, and a second semiconductor layer laminated in order; and
an optical element on which a light emitted from the light emitting module is incident,
wherein
the first semiconductor layer, the core layer, and the second semiconductor layer are arranged along a lamination direction, and
the lamination direction is inclined with respect to a direction perpendicular to an optical axis of the optical element.

2. The optical apparatus according to claim 1, wherein
the light emitting device has a first region and a second region arranged along a propagation direction of the light,
the first semiconductor layer has a thickness greater than a thickness of the second semiconductor layer,
the first semiconductor layer, the core layer, and the second semiconductor layer form a mesa extending along the propagation direction of the light in the first region and the second region, and
the mesa in the second region has a width in a direction intersecting with the propagation direction of the light smaller than a width of the mesa in the first region.

3. The optical apparatus according to claim 2, wherein
the first semiconductor layer has a semiconductor substrate and a first cladding layer,
the second semiconductor layer has a grating layer, a second cladding layer, and a contact layer, and
the grating layer has a diffraction grating in the first region.

4. The optical apparatus according to claim 1, wherein
the lamination direction along which the first semiconductor layer, the core layer, and the second semiconductor layer are laminated is inclined with respect to the direction perpendicular to the optical axis of the optical element by a predetermined angle, and
the predetermined angle is larger than 0 degrees and smaller than 90 degrees.

5. The optical apparatus according to claim 1, wherein
the lamination direction along which the first semiconductor layer, the core layer, and the second semiconductor layer are laminated is inclined with respect to the direction perpendicular to the optical axis of the optical element by a predetermined angle, and
the predetermined angle is greater or equal to 1 degree and less than or equal to 15 degrees.

6. The optical apparatus according to claim 1, wherein
the light emitting module has an emitting window,
the light emitting device and the optical element faces each other across the emitting window, and
the light is incident on the emitting window perpendicularly.

7. The optical apparatus according to claim 1 further comprising:
a base; and
a cap provided on the base and having an emitting window, the cap hermetically sealing the light emitting device,
wherein
the light emitting device and the optical element faces each other across the emitting window, and
the light emitting device is provided on the base so that the lamination direction is inclined with respect to an extending direction of the emitting window by a predetermined angle.

8. The optical apparatus according to claim 1 further comprising:
a base;
a first mount provided on the base; and
a cap provided on the base and having an emitting window, the cap hermetically sealing the light emitting device and the first mount,
wherein
the light emitting device and the optical element faces each other across the emitting window,
the light emitting device is mounted on a mounting surface of the first mount,
the mounting surface of the first mount is inclined from a direction normal to the emitting window by a predetermined angle, and
the lamination direction coincides with a direction normal to the mounting surface of the first mount.

9. The optical apparatus according to claim 1 further comprising:
a base;
a first mount and a second mount provided on a first mounting surface of the base; and
a cap provided on the first mounting surface of the base and having an emitting window, the cap hermetically sealing the light emitting device, the first mount and the second mount,
wherein
the light emitting device and the optical element faces each other across the emitting window,
the first mount is provided on a third mounting surface of the second mount,
the light emitting device is mounted on a second mounting surface of the first mount,
the third mounting surface of the second mount is inclined by a predetermined angle from a direction perpendicular to the emitting window so that the second mounting surface of the first mount is inclined from the direction perpendicular to the emitting window by the predetermined angle, and
the lamination direction coincides with a direction normal to the second mounting surface of the first mount.

10. The optical apparatus according to claim 1 further comprising:
a base;
a first mount and a second mount provided on a first mounting surface of the base; and
a cap provided on the first mounting surface of the base and having an emitting window, the cap hermetically sealing the light emitting device, the first mount and the second mount,
wherein
the light emitting device and the optical element faces each other across the emitting window,
the first mount is provided on a third mounting surface of the second mount,
the light emitting device is mounted on a second mounting surface of the first mount,
the first mounting surface of the base is inclined by a predetermined angle from an extending direction of the emitting window so that the second mounting surface of the first mount is inclined from the direction perpendicular to the emitting window by the predetermined angle, and
the lamination direction coincides with a direction normal to the second mounting surface of the first mount.
